(19) United States
(12) Patent Application Publication
(10) Pub. No.: US 2026/0153812 A1
(43) Pub. Date: Jun. 4, 2026

(54) OPTICAL ASSEMBLY FOR AN EUV PROJECTION EXPOSURE APPARATUS, EUV PROJECTION EXPOSURE APPARATUS

(71) Applicant: Carl Zeiss SMT GmbH, Oberkochen (DE)

(72) Inventors: Dirk EHM, Beckingen (DE); Moritz BECKER, Aalen (DE); Daniel WIDMANN, Weissenhorn (DE)

(21) Appl. No.: 19/457,905

(22) Filed: Jan. 23, 2026

Related U.S. Application Data
(63) Continuation of application No. PCT/EP2024/067962, filed on Jun. 26, 2024.

(30) Foreign Application Priority Data
Jul. 24, 2023 (DE) 10 2023 207 013.8

(51) Int. Cl. G03F 7/00; G01N 21/956; G03F 1/22; G03F 7/20

(52) U.S. Cl. CPC G03F 7/70916; G01N 21/956; G03F 1/22; G03F 7/2004; G03F 7/70033; G03F 7/70233; G03F 7/70316; G03F 7/70825; G03F 7/70958; G01N 2021/95676

(57) ABSTRACT

An optical assembly (100, 200, 300) for an EUV projection exposure apparatus (400) and/or an EUV mask metrology apparatus includes an optical component (101) configured to reflect EUV imaging light (102), a housing (104) that at least partly surrounds the optical component (101) and also encapsulates sections of an EUV beam pathway within the EUV projection exposure apparatus (400) or the EUV mask metrology apparatus, at least one particle trap (106, 206, 306) designed to reduce free particle contamination (105), especially by tin particles, within the housing (104) and having an opening (107, 207, 307) in the direction of the EUV beam pathway. The particle trap (106, 206, 306) is disposed in the housing (104), where the particle trap (106, 206, 306) has an interior and an inner surface (109) surrounding the interior and takes the form of a channel.

### CROSS-REFERENCE TO RELATED APPLICATIONS

This is a Continuation of International Application PCT/EP2024/067962 which has an international filing date of Jun. 26, 2024, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2023 207 013.8 filed on Jul. 24, 2023.

### FIELD

The invention relates to an optical assembly for an EUV projection exposure apparatus and to an EUV mask metrology apparatus, comprising an optical component, a housing that at least partly surrounds the optical component, at least one particle trap configured to reduce free particle contamination and having an opening in the direction of an EUV beam pathway, where the particle trap is disposed in the housing.

The invention further relates to an EUV projection exposure apparatus.

### BACKGROUND

Microlithographic projection exposure apparatuses are used to produce microstructured or nanostructured components for microelectronics or microsystems technology. In order to exactly produce structures with extremely small dimensions in the nanometre and micrometre ranges, a corresponding projection exposure apparatus must be capable of imaging structures contained on a reticle exactly onto a substrate, for example a wafer.

In projection exposure apparatuses configured for the EUV (extreme ultraviolet) range, typically a wavelength of 13.5 nm is used to achieve a corresponding resolution on the substrate. For lack of suitable transmissive materials in this wavelength range, mirrors are used as optical components for the imaging process. Due to the low transmission of all gases at wavelengths in the range of 13.5 nm, it is necessary to operate projection exposure apparatuses of such designs at vacuum pressure conditions.

Because of the required resolution for EUV projection exposure apparatuses, it is necessary that the optical elements or optical components, in particular mirrors, of the projection exposure apparatus have a minimum level of contamination or soiling, especially particulate contamination, on their active optical surfaces. This avoids limitations on the imaging quality caused by soiling.

WO 2008/034582 A2 describes a microlithographic projection exposure apparatus having a housing enclosing an interior and at least one optical component disposed in the housing. The housing that surrounds the interior and the optical component disposed therein serves to reduce contamination, especially in the region of the optical surface of the optical component. By juxtaposing housings, a beam pathway of the light used for the imaging is encapsulated within the projection exposure apparatus. Contamination in an EUV projection exposure apparatus is typically prevented using a gas atmosphere, especially a hydrogen atmosphere.

However, it has been found that, in spite of the disposing of the optical components within housings of a projection exposure apparatus, free particle contamination cannot be ruled out entirely, especially when the particles are distributed along a beam pathway of the light used for the imaging. For example, these may be tin particles that form within a source unit for generation of EUV light and spread out along a beam pathway of the EUV light. These particles within the housings may be deposited, for example, on the inner walls of the housings or on the optical components.

Document DE102017207458A1 describes an EUV projection exposure apparatus comprising at least one particle trap with which extraneous matter is removed from a region of the beam pathway. This particle trap generates at least one electrical and/or magnetic field, with which charged particles are deflected into a trap unit. For this purpose, the particle trap also includes a radiation source with which ionizing radiation is generated from photons irrespective of the working light, in order to ionize the particles to be removed. The particle trap is advantageously in the region of an intermediate focus or at the transition between a light source and an illumination system.

Document DE102015200327A1 describes an assembly for reducing contamination, especially particulate contamination, in an EUV projection exposure apparatus. This assembly is disposed in a region of an intermediate focus of the EUV projection exposure apparatus and includes a separate laser source. The directed electromagnetic radiation from the laser light source brings about evaporation or plasma excitation at least for some of the target material, especially tin, that has entered this region in the operation of the EUV projection exposure apparatus. The material excited in this way can subsequently be bound by a particle trap disposed at the intermediate focus.

### SUMMARY

The solutions described in the prior art for a reduction in a particle count within a projection exposure apparatus are provided in a particular region of the beam pathway, typically in the transition region of a light source into an illumination system. There is no description of an apparatus that can be disposed along the entire beam pathway. The solutions described likewise require an excitation source in order to convert the particulate contaminations to an excited state for removal from the projection exposure apparatus. As well the excitation source, a collection unit is also required for removal of the particulate contamination. The excitation source and the collection unit must be positioned in a particular arrangement relative to one another. These structural prerequisites additionally make it difficult to use the solutions described in the prior art along the entire beam pathway. In addition, these structural prerequisites in turn are sources of contamination within the EUV projection exposure apparatus that should be avoided.

It is therefore an object of the invention to provide an optical assembly for an EUV projection exposure apparatus and an EUV mask metrology apparatus that remedies or at least reduces the disadvantages associated with the solutions proposed by the above-referenced prior art.

This and other objects are achieved in accordance with the features of the independent patent claims.

An optical assembly according to the invention for an EUV projection exposure apparatus and an EUV mask metrology apparatus comprises an optical component configured to reflect an EUV light utilized for the imaging. In addition, the optical assembly according to the invention comprises a housing that at least partly surrounds the optical component and encapsulates sections of an EUV beam pathway within the EUV projection exposure apparatus or the EUV mask metrology apparatus, and at least one particle trap configured to reduce free particle contamination of the housing and having an opening in the direction of the EUV beam pathway. The free particle contamination comprises, e.g., in particular, tin particles. The optical assembly according to the invention is characterized in that the particle trap is disposed in the housing. The particle trap has an interior and an inner surface surrounding the interior, and takes the form of a channel.

The inventors have recognized that particulate contamination, especially tin particles, within the housing surrounding the EUV beam pathway move onward along the beam pathway as a result of elastic impacts within the EUV projection exposure apparatus. The positioning of the particle trap in the housing advantageously reduces an inner surface of the housing required for the onward movement of the particles, and the particle trap is effective directly at the site of arrival of the particles during their intermittent forward movement without a need to provide extensive infrastructure for the removal of particles, for example for excitation of the particles to be removed. This provides a multitude of feasible positions through the housing, especially in the region of the optical component. For example, it is possible to cover the inner surface of the housing completely with particle traps, at least in sections. Because the particle trap is in the form of a channel, particles coming from the housing that have passed through the opening of the particle trap in the direction of the EUV beam pathway are completely surrounded by the particle trap. This increases the probability of constant removal of particles from the opening of the particle trap and/or binding of the particles on the inner walls of the particle trap, while the probability of particles departing from the particle trap back in the direction of the interior of the housing is considerably reduced.

In one embodiment of the optical assembly according to the invention, the particle trap is accommodated by the housing as a cutout therein. In the simplest case, the cutout may take the form of a hole in the housing. This feasible arrangement of the particle trap by virtue of the cutout in the housing allows the opening of the particle trap or a surface that forms the opening to be positioned spatially closer to the inner surface of the housing, which increases the probability of “trapping” of the particles that move within the housing. It is likewise feasible via this arrangement to position a predominant portion of the channel-like structure of the particle trap outside the housing in an advantageous manner. This improves, for example, the accessibility of the particle trap for possible exchange or the disposing of supply elements in the particle trap. Such supply elements may be, for example, a temperature control unit, a conditioning element for providing an electrical potential or an exit region, especially a controllable valve, with which a gas flow through the particle trap is adjustable.

In one embodiment of the optical assembly according to the invention, the particle trap is in linear form. By virtue of this simple symmetric construction of the particle trap, it is possible to achieve ease of manufacturability. For example, by connection of a cylindrical wall element to a circular base element. In the simplest case, a circular tube can be used for the cylindrical wall element. In addition, this embodiment of the optical assembly enables a compact and impervious arrangement of a multitude of particle traps with simultaneously good accessibility, especially when the particle traps are accommodated by the housing.

In one embodiment of the optical assembly according to the invention, the particle trap comprises at least one curved section. The curved section may be executed, for example, as a kink or bend in the channel-like structure of the particle trap. By virtue of this more complex structure, the rear portion of the particle trap does not have a region of direct sight to the opening of the particle trap, which means that the channel-like structure is executed as a labyrinth. By virtue of the curved section, the probability of remobilization of bound particle contamination from the particle trap into the interior of the housing of the optical assembly is further reduced by comparison with the linear structure.

In one embodiment of the optical assembly according to the invention, the particle trap has at least an aspect ratio, defined as the quotient of its length to its diameter, of six. It has been found to be advantageous when a longitudinal extent of the particle trap exceeds a diameter of the particle trap at least by a factor of six. This aspect ratio advantageously increases probability of stable particle binding on the inner surfaces of the particle trap after passing through the opening of the particle trap. Given this aspect ratio, the particles to be bound would have to experience a large and hence improbable number of collisions within the particle trap in order to achieve a reversal of direction within the particle trap and departure from the particle trap.

In one embodiment of the optical assembly according to the invention, the inner surface of the particle trap at least partly comprises a coating of ruthenium, nickel, platinum, rhodium, iridium and/or NiP. These materials have a high binding capacity for particulate contamination, especially for tin particles. It is thus advantageously possible to increase a capacity of the inner surface of the particle trap for particle binding. Typically, the particle trap, especially the inner surface of the particle trap, may consist of stainless steel or aluminium as base material. These base materials are suitable for coating with the aforementioned coating materials. The coating on the inner surface of the particle trap may be formed in regions. As a result, individual regions of the inner surface of the particle trap may be formed in a controlled manner with elevated capacity for binding to particles. These may be, for example, regions of the inner surface of the particle trap that advantageously have a greater distance from the opening of the particle trap by comparison with the other regions of the inner surface.

In one embodiment of the optical assembly according to the invention, the particle trap comprises an entry region and a binding region, where the entry region has a smaller distance from the opening of the particle trap than the binding region. It has been found to be advantageous to promote the binding of the free particle contamination to be removed from the interior of the housing of the optical assembly in a defined region within the particle trap. This is a region of the inner surface of the particle trap at a greater distance from the opening of the particle trap than other regions of the inner surface, which makes it difficult for bound particle contamination to be remobilized into the interior of the housing.

The entry region is a region of the inner surface of the particle trap with a relatively small distance from the opening of the particle trap, where the entry region enables constant transport of the particles to be removed in the direction of the binding region. For this purpose, the inner surface of the entry region has, for example, a surface with high reflection capacity for the particles to be removed or the free particle contamination. By contrast, the inner surface of the binding region has a higher binding capacity for the particles to be removed or the free particle contamination, for example via structuring or coating with a suitable material.

As a result of the separation of the particle trap into the entry region and the binding region, the positioning of particular supply elements, for example a temperature control unit or a conditioning element for provision of an electrical potential, which make it easier or more difficult for particles to be bound, may be restricted to the individual regions. In addition, the separation of the particle trap into the entry region and the binding region can limit exchangeability to individual regions. In the case of exhausted capacity for binding of particles to be removed from the interior of the housing to the inner surface of the particle trap, the exchange may be restricted, for example, to the binding region.

In one embodiment of the optical assembly according to the invention, the entry region at least partly comprises a smooth inner surface having a high reflection capacity for the particles to be removed, where the inner surface of the entry region has an Ra value <0.8 μm. It has been found that an advantageous smooth surface of the inner walls of the entry region of the particle trap with a high reflection capacity for the particles to be removed or the free particle contamination is achieved for an Ra value <0.8 μm. If the particle trap, especially the inner surface, is made from stainless steel or aluminium, for example, an Ra value <0.8 μm is obtainable by electropolishing. The high reflection capacity for particulate contamination, especially for tin contamination, makes it unlikely that the particles to be removed will be bound in the entry region. It is much more likely that they will be transported further into the binding region, where the aforementioned advantages arise.

In one embodiment of the optical assembly according to the invention, the binding region has a structured inner surface with an Ra value >1.6 μm, as a result of which the binding region has an elevated binding capacity for free particle contamination compared to the entry region. The structuring of the inner surface of the binding region advantageously increases a surface area of the binding region which is effective for binding of particles, and an Ra value >1.6 μm has been found to be particularly advantageous. This further increases the probability of binding of the particles to be removed in the binding region compared to the entry region. Such a structured inner surface of the particle trap, especially made of stainless steel or aluminium, is achievable, for example, by grinding, blasting (sand, glass beads), chemical treatment and/or electrochemical treatment.

In one embodiment of the optical assembly according to the invention, the particle trap is in exchangeable form. Since the capacity of the particle trap for binding of further particles of the free particle contamination decreases with increasing conversion of free particles from the interior of the housing to particles bound to the inner surface of the particle trap, the particle trap is exchangeable. Hereby, a particular state of cleanliness within the housing can advantageously be restored constantly. This exchange can be effected in defined cycles, advantageously in breaks in the operation of the projection exposure apparatus. If the particle trap of the optical assembly according to the invention comprises an entry region and a binding region, exchange or exchangeability may be restricted to one of the two regions, especially the binding region.

In one embodiment of the optical assembly according to the invention, the particle trap comprises an exit region, especially at an opposite end of the particle trap from the opening of the particle trap, which enables flow through the particle trap. Flow through the particle trap is enabled via the exit region, especially at the end of the particle trap. For this purpose, the exit region may comprise a controllable valve, for example. Hereby, for example, bound particles are removed from the interior of the particle trap, which further reduces the probability of transport back into the interior of the housing and allows the capacity of the particle trap for removal of particles to be maintained for longer. It is likewise possible that free particles coming from the interior of the housing that pass through the opening of the particle trap are removed from the particle trap via the exit region without being bound to the inner surface thereof. The flow is provided, for example, with a purge gas, especially hydrogen, used in the EUV projection exposure apparatus or in the EUV mask metrology apparatus.

In one embodiment of the optical assembly according to the invention, the particle trap comprises a conditioning element for generation of an electrical potential in at least one subregion of the particle trap. Through the use of the optical assembly according to the invention in an EUV projection exposure apparatus or an EUV mask metrology apparatus, it is possible in operation that particles present in the housing of the optical assembly, especially tin particles, are electrically excited, especially ionized, by the EUV light. In this way, both positively and negatively charged particles may be formed, which can in turn be influenced by an electrical potential, especially when, after being formed, they enter the interior of the particle trap through the opening of the particle trap. The conditioning element can generate a positive potential in at least one subregion of the particle trap, such that binding of negatively charged particles occurs preferentially. Equally, it is alternatively possible to generate a negative potential in at least one subregion of the particle trap, as a result of which preferential binding of positive particles occurs. In principle, therefore, the conditioning element increases effectiveness of the removal of particles by the particle trap in the optical assembly according to the invention.

In one embodiment of the optical assembly according to the invention, an inner surface of the housing at least partly takes the form of a getter surface. A getter surface in the context of this application means an area having an elevated tendency for binding of contamination compared to a surrounding area. These contaminations may be particulate or else gaseous contaminations. The gaseous contamination may especially comprise volatile hydrogen compounds that form in operation of the optical assembly in a hydrogen atmosphere, induced by the EUV light. These may be distributed within the housing and be deposited, for example, on reflective surfaces of the optical component that are utilized for the imaging, which adversely affects the imaging properties. Chemical elements that form these volatile hydrogen compounds are, for example, sulfur, magnesium, phosphorus, manganese, zinc, lead, tin, fluorine or chlorine.

The particulate contaminations, especially tin particles, are contaminations that are removable from the interior of the housing through the at least one particle trap disposed in the housing. Advantageously, therefore, the proportion of free particle contamination within the housing that can move along the beam pathway via elastic impacts is at least reduced by the getter surface. By virtue of the resultant lower proportion of free particle contamination, the capacity of the at least one particle trap for particle removal is maintained for longer.

The getter surface is obtained, for example, by coating of a portion of the inner surface of the housing with ruthenium, nickel, platinum, rhodium, iridium and/or NiP, or in that the housing is formed from these materials at least in sections. It is likewise possible for components coated with these materials or consisting of these materials to be disposed on the inner surface of the housing.

The EUV projection exposure apparatus according to the invention comprises at least one optical assembly in one of the embodiments described. Preferably, a subregion of the EUV projection exposure apparatus, for example an illumination system or a projection system, even more preferably the entire EUV projection exposure system, is formed by an arrangement of different or identical embodiments of the optical assembly according to the invention. As a result, at least in one subregion of and especially throughout the EUV projection exposure apparatus, the EUV beam pathway is encapsulated, as a result of which advantageous reduction in free particle contamination is achievable in these regions.

In one embodiment of the EUV projection exposure apparatus according to the invention, the at least one optical assembly, in one of the embodiments described, is disposed in a region within the EUV projection exposure apparatus with high particle load, especially of tin particles, or in a region with high sensitivity to particle contamination within the project exposure apparatus. In the case of tin particles that can form in the radiation source, for example, an arrangement of one embodiment of the optical assembly in the region of an intermediate focus is advantageous, where the intermediate focus marks the transition of the EUV light from the radiation source into the illumination system. With regard to elevated sensitivity toward particle contamination within the EUV projection exposure apparatus, a suitable example is the providing of the optical assembly in one embodiment that comprises, as optical component, an optical unit composed of micro-mirrors in a single-or multidimensional arrangement, which is preferably movable about at least one axis.

Further features and advantages of the invention will be apparent from the description of working examples of the invention that follows, with reference to the figures, which show details associated with the invention, and from the claims. The individual features can each be implemented individually or together in any combination in a variant of the invention.

### BRIEF DESCRIPTION OF THE DRAWINGS

The invention is described in greater detail hereinafter with reference to exemplary embodiments illustrated with reference to the drawings.

These show, in:

FIG. 1: an optical assembly for an EUV projection exposure apparatus and an EUV mask

metrology apparatus with an optical component, a housing and particle traps in one working example,

FIG. 2: an optical assembly for an EUV projection exposure apparatus and an EUV mask metrology apparatus with an optical component, a housing and particle traps in one working example,

FIG. 3: an optical assembly for an EUV projection exposure apparatus and an EUV mask metrology apparatus with an optical component, a housing and one particle trap in one working example, and

FIG. 4: an EUV projection exposure apparatus in one working example.

### DETAILED DESCRIPTION

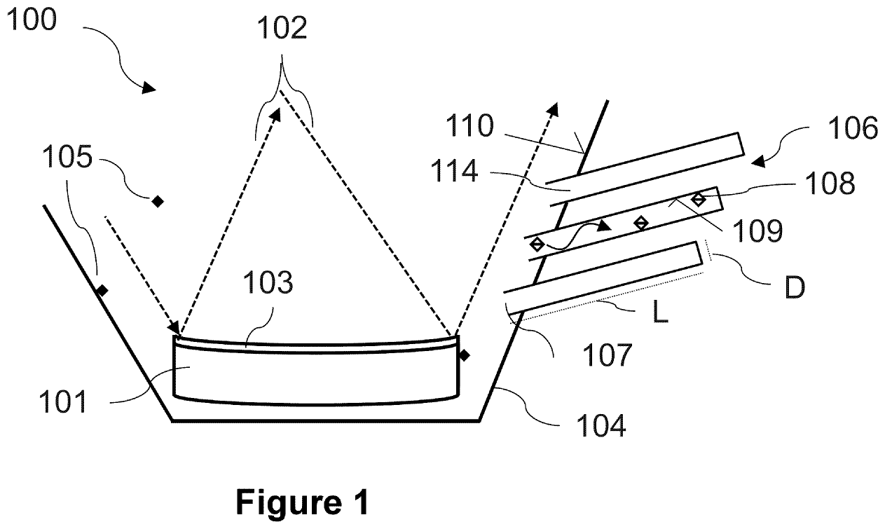

FIG. 1 shows a simplified diagram of an inventive optical assembly 100 for an EUV projection exposure apparatus and an EUV mask metrology apparatus. The optical assembly 100 comprises an optical component 101 configured to reflect an EUV light 102 utilized for imaging. For this purpose, the optical component 101 is coated on a surface with an EUV-reflective coating 103. In addition, the optical assembly comprises a housing 104 that at least partly surrounds the optical component 101 and has an inner surface 110. By virtue of the housing 104, in the interior thereof in the region of the optical component 101, a particularly clean environment which is advantageous for reflection of EUV light 102 is provided. In particular, it is possible to reduce a number of particles on the EUV-reflective coating 103 that can result in possible imaging defects. For this purpose, at least part of the inner surface 110 of the housing 104 may be executed as a getter surface that has an elevated tendency for binding of particulate contamination by comparison with a surrounding surface. The getter surface is obtained, for example, by coating of a portion of the inner surface 110 of the housing 104 with ruthenium, nickel, platinum, rhodium, iridium and/or NiP, or in that the housing 104 is formed from these materials at least in sections. However, even by virtue of the position of the optical component 101 within the housing 104, it is not possible to completely rule out free particle contamination 105, especially when the particles of the free particle contamination 105 are distributed along the beam pathway of the EUV light 102. For example, these may be tin particles that form within a source unit for generation of the EUV light 102 and spread out along the beam pathway of the EUV light 102. These particles in the free particle contamination 105 within the housing 104 may be deposited, for example, on the inner surface 110 of the housing 104 or on the optical component 101.

In order to further reduce the number of particles, or an extent of free particle contamination 105, in an advantageous manner, there are three particle traps 106 disposed in the housing 104 in the working example of FIG. 1. In this example, the particle traps 106 are accommodated by the housing 104 by a cutout 114 therein. The particle traps 106 have a channel-like structure, and in this working example are linear and open on one side with an opening 107 oriented in the direction of the EUV beam pathway. It is possible via the number and positioning of the particle traps to reduce the proportion of free particle contamination 105 in that bound particle contamination 108 is formed and retained within the particle traps 106. This advantageously removes the proportion of bound particle contamination 108 from the free particle contamination 105. This utilizes the effect that a portion of the free particle contamination 105 is distributed within the housing 104 by elastic impacts and will have a certain degree of probability of hitting one of the openings 107. After penetration into the particle traps 106 through the opening 107, the particles at first continue to move by impacts on the inner walls 109 that surround an interior of the particle trap 106. With each impact, there is an increasing probability that the particles will be firmly bound to the inner wall 109, which results in the bound particle contamination 108. In order to reduce the probability of remobilization of the bound particle contamination 108 from the particle traps 106 into the interior of the housing 104, the particle traps 106 are executed with an aspect ratio as the quotient of their length L to their diameter of greater than six. Since a capacity of the particle traps 106 for binding of further particles decreases with continuing conversion of the free particle contamination 105 to the bound particle contamination 108, the particle traps 106 are exchangeable.

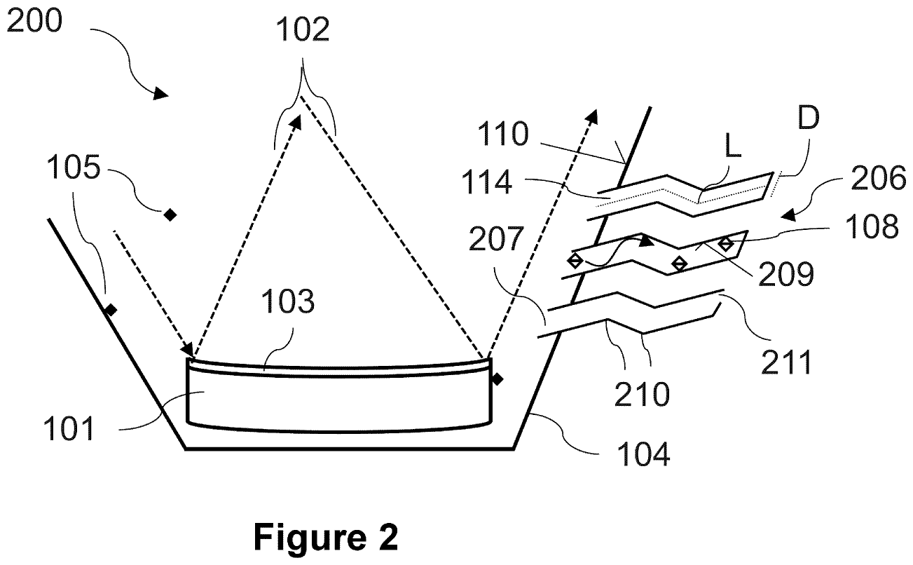

FIG. 2 shows a further simplified diagram of an inventive optical assembly 200 for an EUV projection exposure apparatus and an EUV mask metrology apparatus. The optical assembly 200 likewise comprises the optical component 101, with the EUV-reflective coating 103, configured to reflect the EUV light 102 utilized for imaging. The optical component 101 is likewise within the housing 104, which, for the reasons described in FIG. 1, also contains the free particle contamination 105. The inner surface 110 formed by the housing 104, as shown in the description for FIG. 1, is likewise configured at least partly as a getter surface. For further reduction of free particle contamination 105, the optical assembly comprises three particle traps 206 with an opening 207 oriented in the direction of the EUV beam pathway. These particle traps 206 are disposed in the housing 104 such that the particle traps 206 are accommodated by the housing 104 as a cutout 114 therein.

The particle traps 206 likewise have a channel-like structure, but differ from the particle traps 106 in FIG. 1 by two curved sections 210, executed as a kink in this working example. By virtue of the curved sections 210, the rear portions of the particle traps 206 do not have a region of direct sight to the opening 207, which means that the channel-like structure is executed as a labyrinth. The process of conversion of the free particle contamination 105 to the particle contamination 108 bound to an inner surface 209 of the particle traps 206 is comparable to that according to the working example of FIG. 1.

However, the curved sections 210 further reduce the probability of remobilization of the bound particle contamination 108 from the particle traps 206 into the interior of the housing 104 compared to the working example according to FIG. 1. Furthermore, the particle traps 206 likewise have an aspect ratio, as the quotient of their length L to their diameter D, of at least six. The particle traps 206 may likewise be in exchangeable form for the reasons already described.

In addition, the particle traps 206 may comprise an exit region 211. This is shown in FIG. 2 for the lower of the three particle traps 206, where the exit region 211 at the end of the lower particle trap 206 is opposite the opening 207. Flow through the lower particle trap 206 is enabled via the exit region 211, especially at the end of the lower particle trap 206. For this purpose, the exit region 211 may comprise a controllable valve, for example. Hereby, bound particle contamination 108 can be removed from the interior of the particle trap 206, which further reduces the probability of transport back into the interior of the housing 104 and allows the capacity of the particle trap 206 for removal of particles to be maintained for longer. It is likewise possible that the particles of the free particle contamination 105 coming from the interior of the housing 104 that pass through the opening 207 of the particle trap 206 are removed from the particle trap 206 via the exit region 211 without being bound to the inner surface 209 thereof. The flow is provided, for example, via a purge gas, especially hydrogen, used in an EUV projection exposure apparatus.

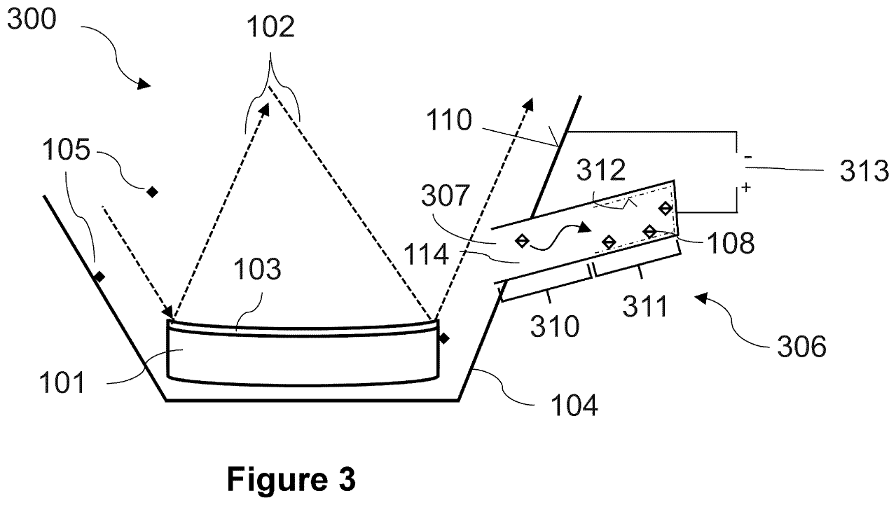

FIG. 3 shows a further simplified diagram of an inventive optical assembly 300 for an EUV projection exposure apparatus and an EUV mask metrology apparatus. The optical assembly 300 likewise comprises the optical component 101, with the EUV-reflective coating 103, configured to reflect the EUV light 102 utilized for imaging. The optical component 101 is likewise within the housing 104, which, for the reasons described in conjunction with FIG. 1, also contains the free particle contamination 105. The inner surface 110 formed by the housing 104, as detailed in the description for FIG. 1, is likewise configured at least partly as a getter surface. For further reduction of free particle contamination 105, the optical assembly 300 comprises a particle trap 306 with an opening 307 in the direction of the EUV beam pathway. This particle trap 306 is disposed in the housing 104 such that the particle trap 306 is accommodated by the housing 104 as a cutout 114 therein. The particle trap 306 likewise has a channel-like structure in linear form.

For improved particle binding and a further reduction in the probability of remobilization of the bound particle contamination 108 from the interior of the particle trap 306 into the interior of the housing 104, the particle trap 306 comprises an entry region 310 and a binding region 311. The entry region 310 has a high reflection capacity for the free particle contamination 105 to be removed from the interior of the housing 104. This is achieved through a smooth surface of the inner walls of the entry region 310 of the particle trap 306, for which purpose the surface has an Ra value <0.8 μm. If the particle trap 306, especially the inner surface, is made from stainless steel or aluminium, for example, an Ra value <0.8 μm is obtainable by electropolishing. The high reflection capacity for particulate contamination, especially for tin contamination, makes it unlikely that the bound particle contamination 108 will be formed in the entry region 310. It is more likely to be transported onward into the binding region 311, which has a coating 312 for formation of a high binding capacity. The coating 312 comprises, for example, ruthenium, nickel, platinum, rhodium, iridium and/or NiP, since these materials have a high binding capacity for particulate contamination, especially for tin particles. In addition, the inner surface of the binding region 311 is structured or roughened with an Ra value >1.6 μm, which increases the surface area effectively utilized for binding. The division of the interior of the particle trap 306 into the entry region 310 and the binding region 311 advantageously achieves a concentration of the bound particle contamination 108 in the downstream region of the particle trap 306. This firstly achieves continuous transport through the entry region 310, since there tends to be only a small proportion of the inner surface of the entry region 310 covered by the bound particle contamination 108. At the same time, remobilization of the bound particle contamination 108 in the interior of the housing 104 is made more difficult since the binding region 311 is positioned further away from the opening 307.

For a further improvement in particle binding and a further reduction in the probability of remobilization of the bound particle contamination 108 from the interior of the particle trap 306 into the interior of the housing 104, the particle trap 306 additionally comprises a conditioning element 313 that generates an electrical potential at least in a subregion of the particle trap 306. In the working example of the optical assembly 300 in FIG. 3, a positive potential is generated in the particle trap 306, such that binding of negatively charged particles occurs preferentially. Equally, it is alternatively possible to generate a negative potential in at least one subregion of the particle trap 306, as a result of which preferential binding of positive particles occurs.

The embodiment of the optical assembly 300 shown in FIG. 3 with the particle trap 306 shows a linear shape of the particle trap. The elements described for improving the removal of particles from the interior of the housing 104, for example the subdivision into the entry region 310 and the binding region 311, the coating 312 and/or the conditioning element 313, however, are equally applicable to a nonlinear particle trap, for example with a labyrinth structure.

Furthermore, the particle trap 306 likewise has an aspect ratio, as the quotient of its length L to its diameter D, of at least six. It is likewise possible for the particle trap 306 to be exchangeable for the reasons already described, where exchangeability may advantageously be limited to the binding region 311. In order to maintain the capacity of the particle trap 306 for particle removal for a longer period of time, the particle trap may likewise comprise an exit region, especially with a controllable valve, in the region opposite the opening 307.

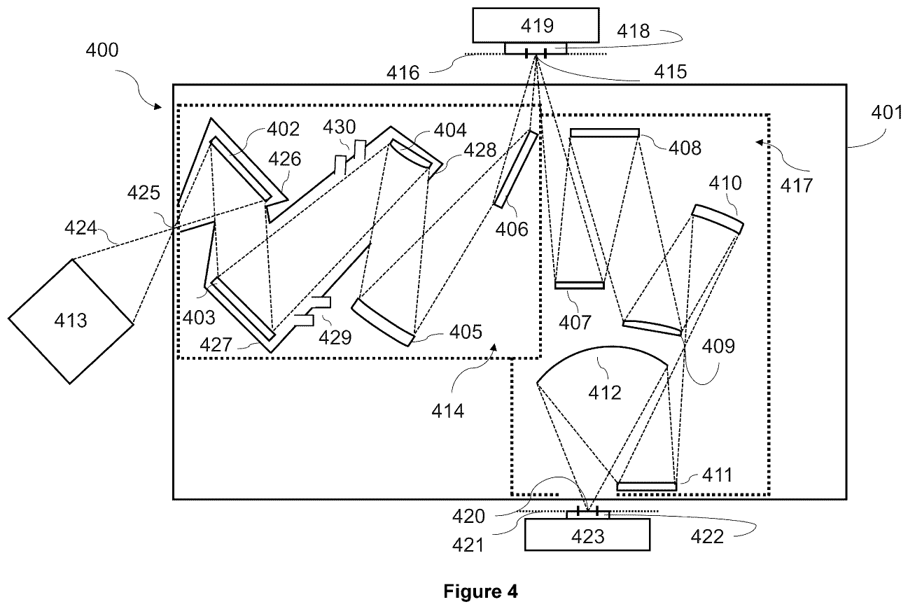

FIG. 4 shows a simplified illustration of an EUV projection exposure apparatus 400 for microlithography. The EUV projection exposure apparatus 400 has a housing 401 that surrounds an interior and has at least one, preferably more than one, optical component 402 to 412 disposed in the housing 401.

The EUV projection exposure apparatus 400 also has, in this working example, a radiation source 413, in particular an EUV light source, an illumination system 414 for illuminating an object field 415 in an object plane 416, and a projection system 417. The illumination system 414 illuminates a reticle 418 which is positioned or positionable in the object field 415 and is held by a reticle holder 419. The projection system 417 is used to image the object field 415 into an image field 420 in an image plane 421. A structure of the reticle 418 is imaged onto a light-sensitive layer of a wafer 422 held by a wafer holder 423 and disposed in the region of the image field 420 in the image plane 421. The wafer is formed in particular from a semiconductor material, for example from silicon.

The radiation source 413 emits EUV radiation 424, in particular in the range of between 5 nm and 30 nm, in particular 13.5 nm. In order to control the radiation path of the EUV radiation 424, at least one of the optical components 402 to 412, in particular each of the optical components 402 to 412, is preferably controllable, in particular for the respective alignability or positionability.

The EUV radiation 424 generated using the radiation source 413 is aligned with a collector mirror (not shown here), which is integrated in the radiation source 413, such that the EUV radiation 424 passes through an intermediate focus 425 in the region of an intermediate focal plane before the EUV radiation 424 is then incident on a first one of the optical components 402, in the present case a field facet mirror 402. Downstream of the field facet mirror 402, the EUV radiation 424 is guided onto a second one of the optical components 403, in the present case a pupil facet mirror 403. Subsequently, the light is guided through the further optical components 404, 405, 406 to the object field 415.

The reticle 418 positioned or positionable in the object field 415 is, for example, a reflective photomask which has reflective and non-reflective, or at least less strongly reflective, regions for generation of at least one structure to be imaged. Alternatively, the reticle 418 is formed by a plurality of micro-mirrors which are arranged in a one-dimensional or multi-dimensional arrangement and are preferably movable about at least one axis.

The reticle 418 reflects some of the EUV radiation 424 coming from the illumination system 414 into the projection system 417 and shapes the light reflected into the projection system 417 such that the information relating to the structure of the reticle 418 is transferred to the image plane 420 with the projection system 417.

In the present working example, the projection lens 417, without being limited to this number, has six optical components or optical elements 407 to 412.

The EUV projection exposure apparatus 400 also has subhousings 426, 427, 428 that are disposed in the housing 401, where each of these subhousings 426, 427, 428 at least partly surrounds one of the optical components 402, 403, 404. The subhousings 426, 427, 428 serve to avoid or at least reduce contamination, especially particle contamination, of the region at least partly surrounded by the subhousings 426, 427, 428, especially contamination of the optical components 402, 403, 404. For this purpose, the inner surfaces of the subhousings 426, 427, 428 may take the form of getter surfaces at least in sections. These subhousings 426, 427, 428 are at least partly joined to one another, such that the subhousings 426, 427, 428 encapsulate the beam pathway of the EUV light 424 formed by the optical components 402, 403, 404 within the illumination system 414.

In spite of the arrangement of the optical components 402, 403, 404 in the subhousings 426, 427, 428, free particle contamination cannot be ruled out entirely, especially when the particles are distributed along the beam pathway of the EUV light 424. For example, these may be tin particles that form within the radiation source 413 for generation of the EUV light 424 and spread out along the beam pathway of the EUV light 424. These particles within the subhousings 426, 427, 428 may be deposited, for example, on the inner walls of the subhousings 426, 427, 428 or on the optical components 402, 403, 404.

In order to further reduce the number of free particles in an advantageous manner in the region of the optical components 402, 403, 404 within the subhousings 426, 427, 428, in the working example of FIG. 4, there are particle traps 429, 430 disposed in the subhousings 427, 428, in that the particle traps 429, 430 are accommodated by the housings 427, 428 as a cutout therein. The particle traps 429, 430 have a channel-like structure, and in this working example are each linear and open on one side with an opening in the direction of the beam pathway of the EUV light 424. The number and positioning of the particle traps 429, 430 allows the proportion of free particles to be reduced. This utilizes the effect that a portion of the free particles is distributed within the housings 426, 427, 428 by elastic impacts and will have a certain degree of probability of hitting the opening of the particle traps 429, 430.

The illustration or positioning of the subhousings 426, 427, 428 with the particle traps 429, 430 in FIG. 4 should be considered to be illustrative. Optionally, the radiation source 413, the reticle holder 419 including the reticle 418 and/or the wafer holder 423 including the wafer 422 and/or the illumination system 414 and/or the projection system 417 are also at least partly enclosed or enclosable by a subhousing having at least one particle trap 429, 430. Additionally or alternatively, at least one optical component 405-412, especially each optical component 405-412, is assigned a subhousing with at least one particle trap.

In the case of arrangement of the subhousings with particle traps in the region of the optical components 402-412 within the EUV projection exposure apparatus 400, regions having a high particle load, especially of tin particles, are specifically chosen. Since, in the case of tin particles, these form in the radiation source 413, it is advisable, for example, to position subhousings with such particle traps in the region of the intermediate focus 425. It is likewise suitable, in a selection of regions within the EUV projection exposure apparatus 400 for the positioning of subhousings with particle traps, to choose regions having high sensitivity to particle contamination within the EUV projection exposure apparatus 400. For example in the region of optical components that are formed from micro-mirrors in a one-or multidimensional arrangement and are preferably movable about at least one axis. It is likewise possible to increase a number of particle traps 429, 430 disposed in a subhousing in a region having a high particle load in the EUV projection exposure apparatus 400, especially of tin particles, or in a region having high sensitivity to particle contamination within the EUV projection exposure apparatus 400. In particular, the entire subhousing may be designed for accommodation of particle traps.

Alternatively, the projection exposure apparatus takes the form of a deep ultraviolet (DUV) projection exposure apparatus, in which case the optical components especially take the form of lens elements and/or mirrors.

In the above working example, an EUV projection exposure apparatus is described. However, the invention is not restricted thereto, but may also be applied to mask metrology apparatuses, for example AIMS (Aerial Image Measurement Technique) apparatuses or APMI (Aerial Pattern Mask Inspection) apparatuses.

### REFERENCE NUMERALS

100 optical assembly
101 optical component
102 EUV light
103 EUV-reflective coating
104 housing
105 free particle contamination
106 particle trap
107 opening of a particle trap
108 bound particle contamination
109 inner surface of the particle trap
110 inner surface of the housing
114 cutout
L length
D diameter
200 optical assembly
206 particle trap
207 opening of a particle trap
209 inner surface of the particle trap
210 curved section
211 exit region
300 optical assembly
306 particle trap
307 opening of a particle trap
310 entry region
311 binding region
312 coating
313 conditioning element
400 EUV projection exposure apparatus
401 housing
402-412 optical components
413 radiation source
414 illumination system
415 object field
416 object plane
417 projection optical unit
418 reticle
419 reticle holder
420 image field
421 image plane
422 wafer
423 wafer holder
424 EUV radiation
425 intermediate focus
426-428 (sub)housing
429 particle trap
430 particle trap

What is claimed is:

1. An optical assembly for an extreme ultraviolet (EUV) projection exposure apparatus and/or an EUV mask metrology apparatus, comprising
an optical component configured to reflect an EUV light utilized for imaging and defining an EUV beam pathway with at least one direction,
a housing that at least partly surrounds the optical component and also encapsulates sections of the EUV beam pathway within the EUV projection exposure apparatus or the EUV mask metrology apparatus,
at least one particle trap configured to reduce free particle contamination within the housing and having an opening oriented in the direction of the EUV beam pathway, wherein the particle trap is disposed in the housing and the particle trap has an interior with an inner surface surrounding the interior and forming a channel.

2. The optical assembly according to claim 1, wherein the free particle contamination comprises tin particles.

3. The optical assembly according to claim 1, wherein the particle trap is accommodated by the housing as a cutout in the housing.

4. The optical assembly according to claim 1, wherein the particle trap is linear in form.

5. The optical assembly according to claim 1, wherein the particle trap comprises at least one curved section.

6. The optical assembly according to claim 1, wherein the particle trap has a length and a diameter having an aspect ratio of at least six, where the aspect ratio is defined as the length divided by the diameter.

7. The optical assembly according to claim 1, wherein the inner surface of the particle trap at least partly comprises a coating of ruthenium, nickel, platinum, rhodium, iridium and/or NiP.

8. The optical assembly according to claim 1, wherein the particle trap comprises an entry region and a binding region, the entry region having a smaller distance than does the binding region to the opening of the particle trap.

9. The optical assembly according to claim 8, wherein the entry region at least partly comprises a smooth inner surface having a high reflection capacity for particles being removed, where the inner surface in the entry region has an Ra value <0.8 μm.

10. The optical assembly according to claim 8, wherein the binding region has a structured inner surface having an Ra value >1.6 μm, such that the binding region has an elevated binding capacity for the free particle contamination relative to the entry region.

11. The optical assembly according to claim 1, wherein the particle trap is configured in exchangeable form.

12. The optical assembly according to claim 1, wherein the particle trap comprises an exit region configured to enable flow through the particle trap.

13. The optical assembly according to claim 12, wherein the exit region is disposed at an end of the particle trap opposite from the opening of the particle trap.

14. The optical assembly according to claim 1, wherein the particle trap comprises a conditioning element configured to generate an electrical potential in at least one subregion of the particle trap.

15. The optical assembly according to claim 1, wherein an inner surface of the housing is configured at least partly as a getter surface.

16. A projection exposure apparatus configured to operate with extreme ultraviolet (EUV) light comprising an optical assembly according to claim 1.

17. The EUV projection exposure apparatus according to claim 16, wherein the EUV projection exposure apparatus has a high particle load region, and the optical assembly is disposed in the high particle load region or in a region with high sensitivity to particle contamination within the projection exposure apparatus.

18. The EUV projection exposure apparatus according to claim 17, wherein the high particle load region comprises a high contamination of tin particles.
